(19) United States
(12) Patent Application Publication
(10) Pub. No.: US 2025/0225298 A1
(43) Pub. Date: Jul. 10, 2025

(54) IDENTIFYING SUBSURFACE HORIZONS OF GEOSPHERE SECTIONS AUTOMATICALLY USING DEEP-LEARNING MODELS

(71) Applicant: Schlumberger Technology Corporation, Sugar Land, TX (US)

(72) Inventors: Nestor Herman Cuevas, Tananger (NO); Michael Hermann Nickel, Tananger (NO); Geir Vaaland Dahl, Tananger (NO); Cylia Hamraoui, Tananger (NO); Dirk Gunnar Steckhan, Tananger (NO)

(21) Appl. No.: 18/407,511

(22) Filed: Jan. 9, 2024

(51) Int. Cl. G06F 30/28

(52) U.S. Cl. CPC G06F 30/28

(57) ABSTRACT

The disclosure focuses on a drilling system that uses a horizon mapping system to actively determine resistivity change interfaces that form a horizon in subsurface geological features. In various implementations, the horizon mapping system uses a resistivity image mapping neural network to efficiently and accurately generate horizon maps of subsurface geological features, such as reservoirs, from resistivity images. Additionally, the horizon mapping system may generate augmented resistivity images labeled with a horizon map in real time as data and measurements are received.

### BACKGROUND

Many natural resources are located underground, including water reservoirs and hydrocarbon reservoirs, such as natural gas and oil. To access these resources, downhole drilling systems drill a wellbore along a trajectory path away from a surface location to a target location, formation, or geological feature. Modern drilling systems use measurements underground to determine the geological features along the trajectory. However, numerous existing drilling systems use inefficient, complex, and labor-intensive methods to interpret subsurface features.

### BRIEF DESCRIPTION OF THE DRAWINGS

The following detailed description provides specific and detailed implementations accompanied by drawings. Additionally, each of the figures listed below corresponds to one or more implementations discussed in this disclosure.

FIG. 1 is a representation of a drilling system for drilling an earth formation to form a wellbore.

FIG. 2 illustrates an example subsurface structure system where a horizon mapping system is implemented in connection with a drilling system.

FIG. 3 illustrates an example block diagram of training a resistivity image mapping neural network with synthetic data within a horizon mapping system to identify horizon boundaries of geological features in geosphere sections.

FIGS. 4A-4B illustrate block diagram examples of using a horizon mapping system to generate horizon maps and augmented resistivity images.

FIG. 5A-5B illustrate block diagram examples of generating the synthetic training data from a resistivity generation model.

FIGS. 6A-6B each illustrate an example series of acts of computer-implemented methods for determining a subsurface horizon in a drilling system.

FIG. 7 illustrates example components included within a computer system.

### DETAILED DESCRIPTION

This disclosure describes a drilling system that uses a horizon mapping system to actively determine resistivity change interfaces that form a horizon in subsurface geological features. In various implementations, the horizon mapping system uses a resistivity image mapping neural network to efficiently and accurately generate horizon maps of subsurface geological features, such as reservoirs, from resistivity images. Additionally, the horizon mapping system may generate augmented resistivity images labeled with a horizon map in real time as data and measurements are received.

In particular, this disclosure relates to devices, systems, and methods for determining subsurface geological feature horizon maps in a drilling system using deep-learning models, synthetic training data, and/or real-time inputs. In this disclosure, these devices, systems, and methods are described in the context of a horizon mapping system, which may automatically delineate the boundaries of reservoirs or other resistivity change interfaces in real time from real-time data from a resistivity image of a geosphere resistivity section. The predicted horizon map accurately generated by the horizon mapping system has numerous applications, such as real-time geosteering and improving downstream models.

According to various implementations, the horizon mapping system receives a resistivity image of a geosphere resistivity section of a subsurface feature. In response, the horizon mapping system generates a horizon map that shows a resistivity change interface using a resistivity image mapping neural network from the resistivity image. In addition, the horizon mapping system generates an augmented resistivity image based on the horizon map and the resistivity image. In some implementations, the horizon mapping system provides the augmented resistivity image for display on a computing device to indicate a horizon boundary within the geosphere resistivity section of the subsurface feature.

In some implementations, the horizon mapping system receives a geosphere inversion image of a geosphere resistivity section of a subsurface feature and generates a horizon map that shows a resistivity change interface using a resistivity image mapping neural network from the geosphere inversion image. Additionally, the horizon mapping system determines a horizon boundary from the horizon map using a map smoothing model. The horizon mapping system also generates an augmented geosphere inversion image by combining the horizon boundary with the geosphere inversion image.

As described in this disclosure, including the following paragraphs, the horizon mapping system delivers several significant technical benefits in terms of computing efficiency, accuracy, and flexibility compared to existing systems. Moreover, the horizon mapping system provides practical applications that address problems related to determining a horizon mapping of reservoir boundaries and/or other resistivity change interfaces of subsurface geological features in real-time within drilling systems. For example, in some instances, the geological insights generated by the horizon mapping system play a crucial role in enabling real-time auto-geosteering.

As previously mentioned, existing drilling systems suffer from several problems that result in inefficiencies and inaccuracies. Many of these systems rely on experts, such as well placement experts (WPEs), to manually decipher, decode, and estimate reservoir boundaries from captured downhole data. This manual approach often leads to inconsistent and inaccurate results due to subjective differences among experts. Furthermore, when attempting to perform these tasks in real-time, the high-intensity nature of the work frequently leads to errors by experts, which are only discovered when drilling unexpectedly breaches a reservoir boundary

Additionally, existing systems struggle to effectively utilize seismic and resistivity data to accurately detect geological subsurfaces. This lack of accuracy also impacts the ability to interpret and predict resistivity change interfaces ahead of the drill, resulting in reactive rather than proactive actions. Another issue is the delay that occurs in existing systems when determining boundaries in geosphere sections.

While some existing systems are attempting to automate the boundary detection process, these may be encumbered with random noises and potential artifacts. These systems may be challenged to meet the minimum accuracy and efficiency standards. Furthermore, many of these systems rely on their own set of experts who compete against instead of working together to leverage and incorporate their knowledge as an asset to improve prediction results.

In contrast to existing systems, the horizon mapping system generates highly accurate predictions of horizon maps. In various implementations, the horizon mapping system uses a resistivity image mapping neural network that leverages deep-learning methods to efficiently predict accurate horizon maps from resistivity images, including geosphere inversion images. Additionally, the horizon mapping system uses horizon maps to generate augmented or labeled resistivity images and/or inversion images in real time.

In addition to providing highly accurate results, the horizon mapping system ensures consistency in its results while providing highly accurate results. In various implementations, the horizon mapping system generates and utilizes synthetic data to fine-tune the resistivity image mapping neural network, allowing it to quickly generate accurate horizon maps from real-time data. This reduces, or at least significantly minimizes, the need for expert input in the process.

Furthermore, the reservoir boundary prediction results generated by the horizon mapping system contribute to various practical applications. For example, the horizon mapping system generates horizon maps, which may indicate reservoir boundaries, in real time. The horizon maps may be used by a drilling system to determine a trajectory path with high accuracy, to enable auto-geosteering of a corresponding drill, and to improve the accuracy of downstream models and workflows that rely on precise knowledge of reservoir boundary mapping.

As illustrated in the following discussion, this disclosure uses a variety of terms to describe the features and advantages of one or more implementations described in this disclosure. Additional details are provided to clarify the meaning of some of these terms, while details regarding other terms may be provided later in the document.

In this disclosure, the term “geosphere” refers to the solid parts of the Earth. For example, it includes rocks, minerals, and layers making up Earth's interior. In some instances, the term geosphere also includes molten lava and/or magma. The term “geosphere section” refers to a part of the geosphere that is being studied or analyzed. Often, a geosphere section is captured within an image. A geosphere section may be represented as a single dimension or multiple dimensions (e.g., 1D, 2D, 3D, or n-D). In various implementations, a geosphere section includes seismic and/or resistivity data.

The term “resistivity image” refers to an image that includes resistivity measurements of subsurface geological features. A resistivity image may include a geosphere inversion image and/or electromagnetic (EM) field measurements and/or mappings of a surrounding area of a wellbore measured using a downhole resistivity sensor. In some instances, the measurements are in a specific direction, typically along the length of the borehole or drill hole, which is done to gather information about subsurface structures and geological formations.

The term “geosphere inversion image” (or “inversion image” for short) refers to a graphical representation of the subsurface geology of a particular geosphere section captured by analyzing data from electromagnetic surveys that measure the electrical conductivity of rocks, minerals, and other geological features. A geosphere section may include one or more inversion images. Components of a drilling system may measure, generate, and provide inversion images in real time to the horizon mapping system to generate horizon maps.

The term “reservoir” refers to a subsurface rock formation with sufficient porosity and permeability to store and transmit fluids, often hydrocarbons or water. The term “reservoir boundary” refers to the outer limit or edge of an underground geological formation that contains a significant quantity of hydrocarbons, such as oil or natural gas. A reservoir boundary defines the area within which valuable hydrocarbon resources are trapped and may be extracted. Reservoir boundaries are crucial for determining the size and extent of a reservoir. Typically, reservoir boundaries are determined by geological factors such as rock types, stratigraphy, and structural features like faults or anticlines. Reservoir boundaries usually encompass a top or ceiling boundary and a bottom or base boundary. Reservoir boundaries may also include side, cap, or end boundaries.

The term “augmented resistivity image” refers to an inversion image that includes labels or another type of indication adding information to and/or modifying the original inversion image. For example, an augmented resistivity image includes reservoir boundary labels showing a top border and/or a base border. Additionally, an augmented resistivity image shows where resistivity changes occur indicating the change from one geological feature to another (e.g., between rock, minerals, hydrocarbons, water, shale, etc.). In some instances, an augmented resistivity image includes an augmented inversion image.

As used herein, a “geological feature” may be any element of a geological formation. For instance, a geological feature may include a geological structure, such as a formation. A geological feature may include the entire geological structure. A geological feature may include a volume of space, including one or more structures, rock types, material types, and so forth. In some embodiments, a geological feature may include a boundary between two geological structures, such as a boundary between strata. In some embodiments, a geological feature may include a boundary between rock types. In some embodiments, a geological feature may include a specific structure of a set of structures, such as a fluid reservoir. A geological feature may be 3-dimensional. For example, a geological feature may include a 3-dimensional surface having variations in latitude, longitude, and depth.

As used herein, the term “uphole” refers to a direction of a wellbore, taken from the bit or another feature of the drilling system, that is disposed toward the collar of the wellbore or a location that is closer to the collar of the wellbore. The term “downhole” refers to a direction of the drilling system that is disposed away from the collar of the wellbore or a location that is toward the drill bit and moving away from the collar of the wellbore. The term downhole may also include the target path or trajectory of the wellbore beyond the drill bit within the wellbore (e.g., earth not yet drilled).

The term “machine-learning model” refers to a computer model or computer representation that may be trained (e.g., optimized) based on inputs to approximate unknown functions. For instance, a machine-learning model may include, but is not limited to, a neural network (e.g., a convolutional neural network (CNN) or deep learning model), a decision tree (e.g., a gradient-boosted decision tree), a linear regression model, a logistic regression model, or a combination of these models.

As another example, the term “neural network” refers to a machine learning model comprising interconnected artificial neurons that communicate and learn to approximate complex functions, generating outputs based on multiple inputs provided to the model. For instance, a neural network includes an algorithm (or set of algorithms) that employs deep learning techniques and uses training data to adjust the parameters of the network and model high-level abstractions in data. Various types of neural networks exist, such as convolutional neural networks (CNNs), residual learning neural networks, recurrent neural networks (RNNs), generative neural networks, generative adversarial neural networks (GANs), and single-shot detection (SSD) networks.

Additional terms are defined throughout the disclosure in connection with various examples and contexts.

Turning now to the figures, additional details are provided regarding the components and features of the horizon mapping system. Additional example implementations and details of the horizon mapping system are discussed in connection with the accompanying figures.

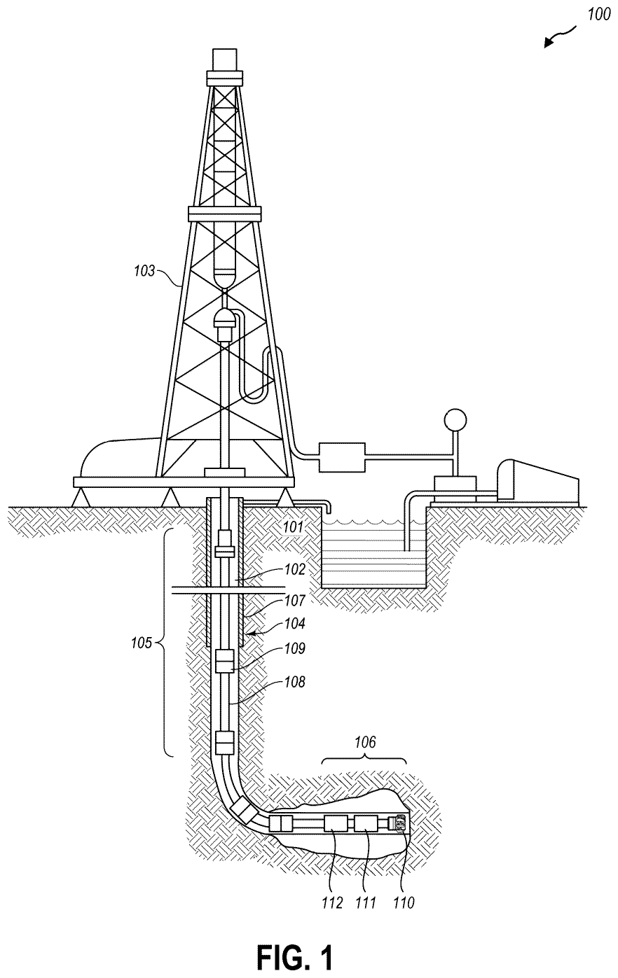

FIG. 1 shows an example representation of a drilling system for drilling an earth formation to create a wellbore. FIG. 1 provides context regarding a drilling system to which the horizon mapping system often belongs. To illustrate, FIG. 1 shows one example of a drilling system 100 used for drilling an earth formation 101 to form a wellbore 102. The drilling system 100 includes a drill rig 103 used to rotate a drilling tool assembly 104 that extends downward into the wellbore 102. The drilling tool assembly 104 may include a drill string 105, a bottomhole assembly (BHA 106), and a bit 110, attached to the downhole end of the drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 may further include additional components such as subs, pup joints, etc. The drill pipe 108 provides a hydraulic passage through which drilling fluid is pumped from the surface. The drilling fluid discharges through nozzles, jets, or other openings in the bit 110 for purposes such as cooling the bit 110 and its cutting structures, lifting cuttings out of the wellbore 102 during drilling, controlling fluid influx in the well, maintaining wellbore integrity, and other functions.

The BHA 106 may include the bit 110 or other components. An example BHA 106 may include additional or different components (e.g., coupled between the drill string 105 and the bit 110). Examples of additional BHA components include drill collars, stabilizers, measurement-while-drilling (MWD) tools, logging-while-drilling (LWD) tools, downhole motors, underreamers, section mills, hydraulic disconnects, jars, vibration or damping tools, other components, or combinations of these components.

The BHA 106 may further include a directional tool 111 such as a bent housing motor or a rotary steerable system (RSS). The directional tool 111 may include directional drilling equipment that changes the direction of the bit 110, thereby altering the trajectory of the wellbore 102. In some cases, at least a portion of the directional tool 111 may maintain a geostationary position relative to an absolute reference frame, such as gravity, magnetic north, or true north. Using measurements obtained from this geostationary position, the directional tool 111 may locate the bit 110, modify its course, and guide the directional tool 111 along a projected trajectory. For instance, the BHA 106 (including the directional tool 111) is shown transitioning from vertical to horizontal drilling, causing the bit 110 to move along a horizontal path away from the drill rig 103.

In general, the drilling system 100 may include additional or different drilling components and accessories including special valves (e.g., blowout preventers and safety valves). Additional components within the drilling system 100 may be categorized as part of the drilling tool assembly 104, the drill string 105, or part of the BHA 106 depending on their specific locations within the drilling system 100.

The bit 110 in the BHA 106 may be any type of bit suitable for degrading downhole materials such as the earth formation 101. Examples of drill bits used for drilling earth formations include fixed-cutter or drag bits, roller cone bits, and combinations thereof. In other embodiments, the bit 110 may be a mill used for removing metal, composite, elastomer, or other downhole materials, or combinations thereof. For instance, the bit 110 may be used with a whipstock to mill into the casing 107 lining the wellbore 102. The bit 110 may also be a junk mill used to mill away tools, plugs, cement, or other materials within the wellbore 102, or combinations thereof. Swarf or other cuttings formed by the use of a mill may be lifted to the surface or allowed to fall downhole. In still other embodiments, the bit 110 may include a reamer. For instance, an underreamer may be used in connection with a drill bit, and the drill bit may bore into the formation while the underreamer enlarges the size of the bore.

While performing drilling activities, a subsurface structure system may prepare geological projections of various geological features of the earth formation 101 (e.g., geological projections of geological maps, cross sections, 3D models, seismic reflection profiles, or contour maps). These projections may be located around geological features of interest, such as formations to be drilled through, reservoir boundaries, and so forth. A drilling operator may prepare a target trajectory or target path for the wellbore 102. For example, the wellbore 102 may follow a projected trajectory based on the projected geological features. The projected trajectory may avoid crossing the projected geological feature.

The subsurface structure system may receive information regarding the earth formation 101 based on one or more sets of survey data. For example, the geological projection system may receive seismic survey data from a seismic survey. The seismic survey may be conducted from the surface of the drilling system 100 and may include seismic data for a large portion of the earth formation 101, including the target path of the wellbore 102. Using the seismic data, the geological projection system may identify one or more seismic surfaces of a geological feature.

The BHA 106 may include resistivity sensors 112 (e.g., a downhole resistivity sensor). The resistivity sensors 112 may collect resistivity sensor data from the earth formation 101 uphole of the bit 110. Resistivity sensor data may be collected by transmitting an electromagnetic field through the earth formation 101. The variation in the electromagnetic field through the earth formation 101 may represent the resistivity of the earth formation 101.

Resistivity sensor data may be used to determine the geological properties of the earth formation 101. For example, the resistivity sensor data may be used to determine one or more geological surfaces or structures. In some situations, the sensed surface of the geological features determined using the resistivity sensor data may be more accurate or representative of the actual geological feature of the earth formation 101 than the seismic surface. This may be because one or more of the resistivity sensors 112 are located downhole and therefore closer to the relevant geological structures of the earth formation 101 than the seismic survey instrument.

As described in this disclosure, the horizon mapping system may use measurements, such as geosphere resistivity sections and resistivity images that include resistivity data, to determine horizon maps and/or reservoir boundaries of geological surfaces or structures. In particular, the horizon mapping system uses one or more deep-learning models (e.g., a resistivity image mapping neural network) to accurately predict reservoir boundaries of subsurface reservoirs within horizon maps.

In some instances, the horizon mapping system automatically corrects and/or enables a drilling operator to make more informed decisions regarding drilling parameters, including the trajectory of the wellbore. For example, based on the reservoir boundaries, the horizon mapping system modifies a projected trajectory of a wellbore to avoid a particular reservoir boundary. This may help improve wellbore quality, reduce wear and tear on drilling equipment, improve the rate of penetration, improve wellbore production, and provide other benefits.

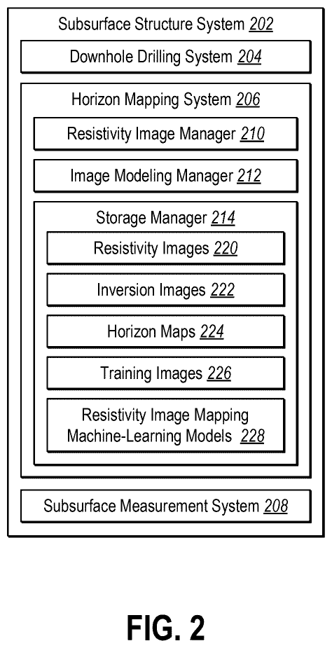

With the framework of the drilling system and an example operating environment described, this disclosure will now focus on describing implementations of the horizon mapping system. To illustrate, FIG. 2 shows an example of a subsurface structure system 202 implementing a horizon mapping system 206. The subsurface structure system 202 includes various computing devices and systems. As shown, the subsurface structure system 202 includes a downhole drilling system 204, the horizon mapping system 206, and a subsurface measurement system 208. Each of these systems may be implemented on one or more computing devices.

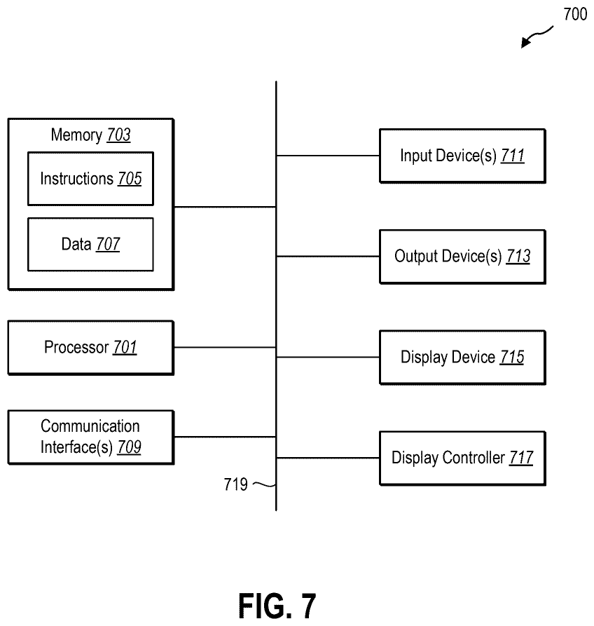

The subsurface structure system 202 may include additional devices and components not shown. Additionally, while FIG. 2 shows example arrangements and configurations of the subsurface structure system 202 and/or the horizon mapping system 206, other arrangements and configurations are possible. Further, details regarding computing devices are provided below in connection with FIG. 7.

In various implementations, the downhole drilling system 204 precisely controls the direction and trajectory of a drill and/or wellbore as it progresses through the subsurface formations. In various instances, a downhole drilling system 204 uses real-time data analysis with precise drilling control to navigate through subsurface formations, maximize reservoir contact, minimize drilling risks, and optimize the placement of wellbores in hydrocarbon reservoirs. The downhole drilling system 204 operates with the horizon mapping system 206 to identify reservoir boundaries and perform drill control optimization. In various implementations, the downhole drilling system 204 automatically modifies a projected trajectory based on reservoir boundaries provided by the horizon mapping system 206.

In some implementations, the subsurface measurement system 208 uses one or more tools to collect and analyze data from below the Earth's surface. The subsurface measurement system 208 may use various instruments and methods designed for measuring and monitoring conditions, properties, and processes in subsurface environments, such as underground reservoirs, geological formations, and aquifers. In various implementations, a subsurface measurement system 208 includes sensors, probes, well-logging equipment, and remote sensing technologies to provide subsurface information. For example, the subsurface measurement system 208 uses downhole resistivity sensors to provide subsurface resistivity measurements, which may be used to generate geosphere resistivity sections and resistivity images of a wellbore. Additionally, in some instances, the subsurface measurement system 208 creates 1D, 2D, or 3D representations of a subsurface area, which may indicate crucial geological features and rock properties.

As shown, the subsurface structure system 202 includes the horizon mapping system 206, which may communicate with the downhole drilling system 204 and the subsurface measurement system 208. The horizon mapping system 206 includes various components to implement the functions, features, systems, and methods described in this document. To illustrate, the horizon mapping system 206 includes a resistivity image manager 210, an image modeling manager 212, and a storage manager 214. The storage manager 214 includes resistivity images 220, inversion images 222, horizon maps 224, training images 226, and resistivity image mapping machine-learning models 228. The horizon mapping system 206 may include additional or different components, as previously mentioned above.

The horizon mapping system 206 may be located as part of a downhole assembly, located at the surface, or located at various locations. For example, in some instances, the horizon mapping system 206 is located near a downhole resistivity sensor near the drill and determines reservoir boundaries in real-time as data is received. In some implementations, the horizon mapping system 206 determines reservoir boundaries at the surface and allows WPEs to modify a trajectory path based on the reservoir boundaries it determines.

In various implementations, the resistivity image manager 210 obtains resistivity images 220 and inversion images 222 from the subsurface measurement system 208. In many instances, the resistivity image manager 210 obtains the inversion images in real-time. The resistivity image manager 210 may provide the inversion images 222 to the image modeling manager 212 to determine horizon maps 224 and/or reservoir boundaries within the resistivity images 220 and/or inversion images 222 from a geosphere section.

In various implementations, the image modeling manager 212 determines horizon maps 224 for a subsurface geological feature, such as a reservoir, detected in resistivity images 220. For example, the image modeling manager 212 uses one or more of the resistivity image mapping machine-learning models 228 to generate horizon maps 224. The resistivity image mapping machine-learning models 228 may include different types of resistivity image mapping neural networks, such as image segmentation machine-learning models with neural network architectures (e.g., Monte Carlo Dropout prediction model, U-Net, U-Net++, Mask R-CNN, transformer-based models, large generative model-based segmentation neural networks, etc.).

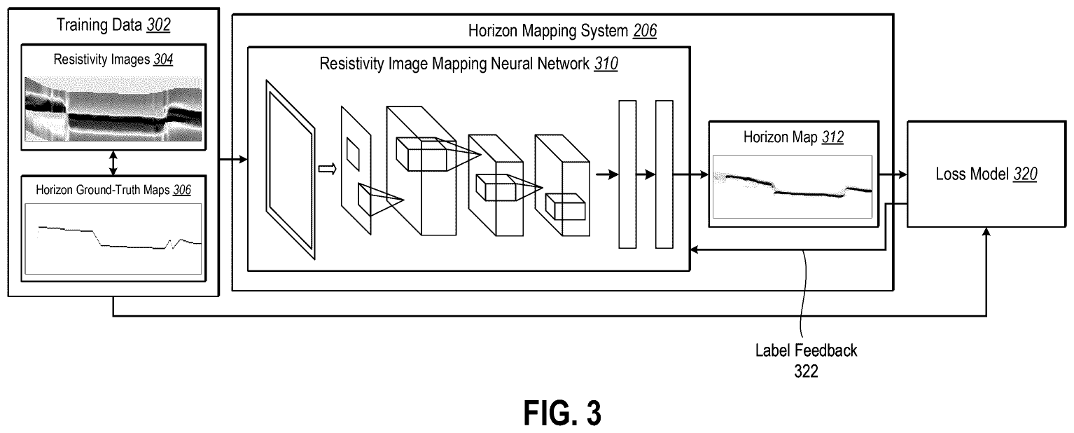

Based on the horizon maps 224, the image modeling manager 212 may generate augmented resistivity images indicating the location of boundaries between different types of subsurface geological features. Additional details regarding determining horizon maps and/or reservoir boundaries using resistivity image mapping machine-learning models are provided below in connection with FIG. 3.

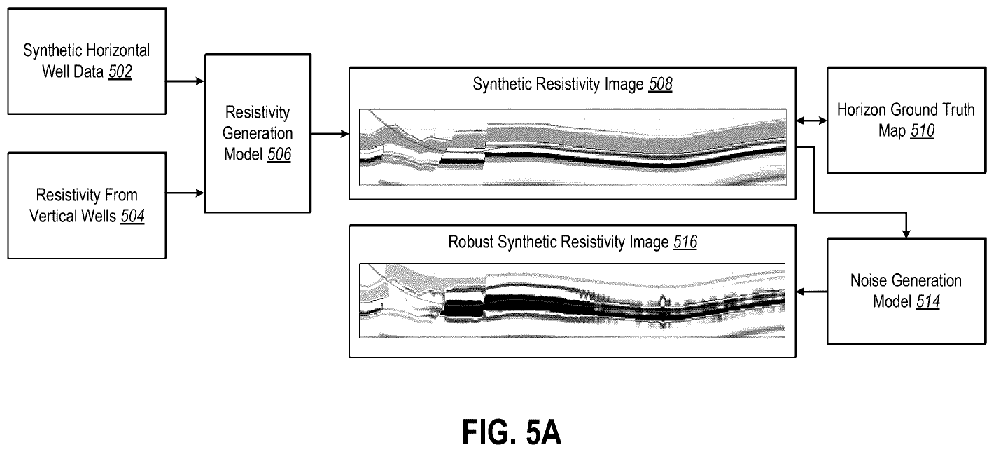

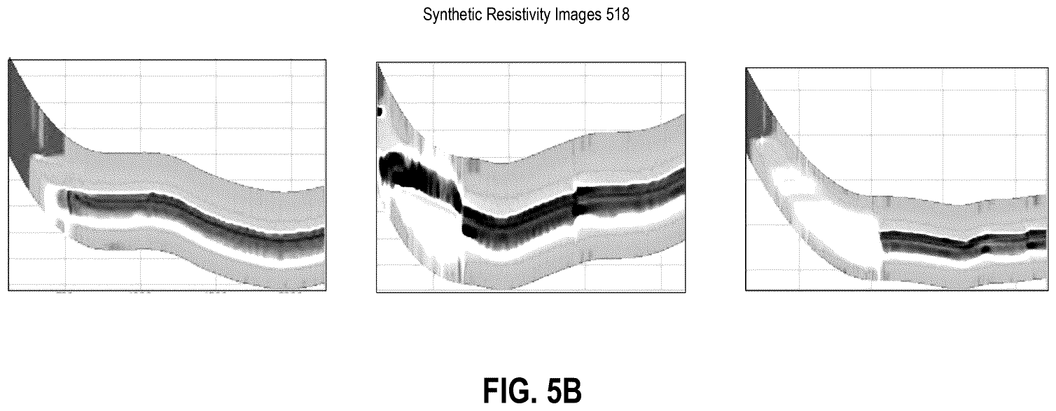

In various implementations, the image modeling manager 212 generates training images 226 that include non-labeled and corresponding labeled images to train a machine-learning model. In many instances, the training images 226 are based on synthetically generated data. Additionally, FIG. 3 and FIG. 5A illustrate the generation of training data to train one or more resistivity image mapping neural networks.

Each of the components of the subsurface structure system 202 and/or the horizon mapping system 206 may be implemented in software, hardware, or both. For example, the components of the horizon mapping system 206 include instructions stored on a computer-readable storage medium and executable by at least one processor of one or more computing devices. When executed by the processor, the computer-executable instructions of the subsurface structure system 202 cause a computing device to perform the methods described herein. As another example, the components of the horizon mapping system 206 include hardware, such as a special-purpose processing device to perform a certain function or group of functions. In some instances, the components of the horizon mapping system 206 include a combination of computer-executable instructions and hardware.

Furthermore, the components of the subsurface structure system 202 and/or the horizon mapping system 206 may be implemented as one or more operating systems, stand-alone applications, modules of an application, plug-ins, library functions, functions called by other applications, and/or cloud-computing models. Additionally, the components of the horizon mapping system 206 may be implemented as one or more web-based applications hosted on a remote server and/or implemented within a suite of mobile device applications or “apps.”

As previously mentioned, the horizon mapping system 206 uses a resistivity image mapping neural network to generate horizon maps. These horizon maps indicate resistivity change interfaces of subsurface geological features, such as reservoir boundaries, adjacent to or in front of a wellbore. Accordingly, FIG. 3 illustrates an example block diagram of training a resistivity image mapping neural network with synthetic data within a horizon mapping system to identify horizon boundaries of geological features in geosphere sections according to some implementations.

As also mentioned earlier, FIG. 3 illustrates an example block diagram of the training of a resistivity image mapping neural network to generate horizon maps. As shown, FIG. 3 includes training data 302, the resistivity image mapping neural network 310, and a loss model 320. The training data 302 includes resistivity images 304 and horizon ground-truth maps 306 corresponding to the resistivity images 304. In one or more implementations, the resistivity images 304 are generated from synthetic modeling and data. Additional details regarding generating the training data 302 are provided below in connection with FIGS. 5A-5B.

FIG. 3 also includes the resistivity image mapping neural network 310. In various implementations, such as the one shown, the resistivity image mapping neural network 310 includes a neural network architecture, such as higher and lower neural network layers. For example, the resistivity image mapping neural network 310 is an image segmentation neural network, similar to one or more of the machine-learning model types described above. In various instances, the resistivity image mapping neural network 310 is a Monte Carlo Dropout prediction model, a U-Net neural network, or a U-Net++ neural network. In some instances, the resistivity image mapping neural network 310 is a large generative model, such as a large language model, or a multi-modal image-to-image neural network.

To elaborate, in some instances, the resistivity image mapping neural network 310 is a convolutional neural network (CNN) that includes several neural network layers, such as lower neural network layers that form an encoder, and higher neural network layers that form a decoder. For example, the encoder maps or encodes input images into feature vectors (i.e., latent object feature maps or latent object feature vectors) by processing each input image through various neural network layers (e.g., convolutional, ReLU, and/or pooling layers) to encode pixel data from the input images into feature vectors (e.g., a string of numbers in vector space representing the encoded image data). For instance, the encoder of a resistivity image mapping neural network processes input images to encode image features corresponding to resistivity change interfaces, horizons, and/or reservoir boundaries from the resistivity images 304 (e.g., inversion images).

Additionally, in various implementations, the resistivity image mapping neural network 310 includes higher neural network layers that form a decoder, which may include fully connected layers and/or a classifier function (e.g., a SoftMax or a sigmoid function). In these implementations, the decoder processes the feature vectors to decode detected resistivity change interfaces, horizons, and/or reservoir boundaries in an encoded image vector and generate a horizon map indicating portions of the input image that form a horizon between two subsurface geological features (e.g., a reservoir boundary). The resistivity image mapping neural network 310 is often trained offline but may be trained on the fly.

In some implementations, the resistivity image mapping neural network 310 corresponds to detecting a single horizon, such as a top boundary of a reservoir. In some instances, this resistivity image mapping neural network determines multiple top boundary horizons of a reservoir. Additionally, in these implementations, the horizon mapping system 206 may generate and fine-tune another model to determine a bottom boundary of the reservoir. Additionally, the horizon mapping system 206 may generate and use additional resistivity image mapping neural networks to determine other resistivity change interfaces with subsurface geological features, such as a water or oil contact horizon, or another material horizon within a reservoir. In these instances, the horizon mapping system 206 utilizes separate resistivity image mapping neural networks that are precise and highly accurate at determining a specific type of horizon map.

In some implementations, the horizon mapping system 206 generates and/or trains a resistivity image mapping neural network to determine a horizon map that includes different horizons. For example, in some instances, the resistivity image mapping neural network 310 generates a horizon map that includes both the top and bottom/base horizons of a reservoir. In these instances, the resistivity image mapping neural network 310 provides improved efficiency by determining multiple horizon types at the same time.

The horizon mapping system 206 may provide a combination of the above examples. For example, the horizon mapping system 206 generates a combined resistivity image mapping neural network that determines the top and bottom of a reservoir along with one or more separate resistivity image mapping neural networks that determine other horizons within the reservoir (e.g., water contact, oil contact, or shale).

As shown, the resistivity image mapping neural network 310 generates a horizon map 312. The horizon map 312 indicates a horizon that corresponds to an input image. In some instances, the horizon map 312 is an image mask that includes different pixels indicating a horizon. For example, the resistivity image mapping neural network 310 indicates the pixels in a horizon map 312 that belong to a determined horizon.

In one or more implementations, the resistivity image mapping neural network 310 utilizes a probability distribution function (PDF) to generate the horizon map 312. In some implementations, the horizon mapping system 206 trains the resistivity image mapping neural network 310 to determine a PDF mean, which represents a reservoir boundary (e.g., the top reservoir boundary) and a PDF uncertainty. For example, the resistivity image mapping neural network 310 applies Formula 1 to determine the PDF mean and Formula 2 to determine the uncertainty.

$$\sum \{ z \} = 〈 z 〉 = {\int }_{- ∞}^{∞} z {f}_{Y} ( z ) dz \qquad Formula 1$$

$$\sum \{ {( z - 〈 z 〉 )}^{2} \} = Var = {\int }_{- ∞}^{∞} {( z - 〈 z 〉 )}^{2} {f}_{Y} ( z ) d z \qquad Formula 2$$

Additionally, in various implementations, when the horizon mapping system 206 provides input to the resistivity image mapping neural network 310, such as an inverted resistivity section, the resistivity image mapping neural network 310 generates an output that includes a reservoir boundary surface (e.g., the surface of a Top Reservoir Boundary) with coordinates (e.g., X, Y, Z). Further, in various implementations, the output also includes two uncertainty surfaces associated with the reservoir boundary surface, such as a first uncertainty surface above and a second uncertainty surface below the reservoir boundary surface. For example, the horizon map 312 includes a top reservoir boundary with uncertainty surface lines both above and below the reservoir boundary surface.

In various implementations, the horizon map 312 includes a pixel intensity that correlates to the probability that the pixel corresponds to a horizon. For example, the pixel brightness at each location corresponds to the probability that the resistivity image mapping neural network 310 predicts the pixels belonging to a horizon, where the brightness fades as the distance from the predicted horizon increases. In these instances, the horizon mapping system 206 provides indications of horizon uncertainty within the horizon map. Also, in some of these instances, the horizon map 312 may be in grayscale or another color scheme.

As shown in FIG. 3, the loss model 320 is included, which may have one or more loss functions (e.g., cross-entropy loss and/or image similarity loss). In various implementations, the horizon mapping system 206 uses the loss model 320 to determine an error or loss amount, which the horizon mapping system 206 provides back to the resistivity image mapping neural network 310 as label feedback 322 to train and fine-tune the resistivity image mapping neural networks.

To further elaborate, in various implementations, the horizon mapping system 206 compares the horizon ground-truth maps 306 to the horizon map 312 using the loss model 320 to generate the label feedback 322 indicating an error or loss amount. The horizon map 312 is generated by the resistivity image mapping neural network 310 based on resistivity images 304 corresponding to the horizon ground-truth maps 306.

Additionally, in one or more implementations, the horizon mapping system 206 uses the label feedback 322 to train, optimize, and/or fine-tune the neural network layers of the resistivity image mapping neural networks through techniques like backpropagation and/or end-to-end learning. In some implementations, the horizon mapping system 206 uses an optimizer algorithm such as the Adam optimizer and/or another optimization algorithm for stochastic gradient descent (SGD) to train the deep learning models. Furthermore, the horizon mapping system 206 may iteratively fine-tune and train the resistivity image mapping neural networks until they converge, for a set number of iterations, until the training data is exhausted, or until a satisfactory level of accuracy is achieved.

In various implementations, the horizon mapping system 206 uses different data augmentation techniques and n-fold ensembles. For instance, the horizon mapping system 206 augments the training data 302 to increase the robustness of the resistivity image mapping neural networks. For example, the horizon mapping system 206 creates instances of the training data 302 that are horizontally and/or vertically flipped, randomly rotated up to 90 degrees, randomly adjusted for brightness and contrast levels, subjected to color jittering, and/or modified based on random Gaussian noise values.

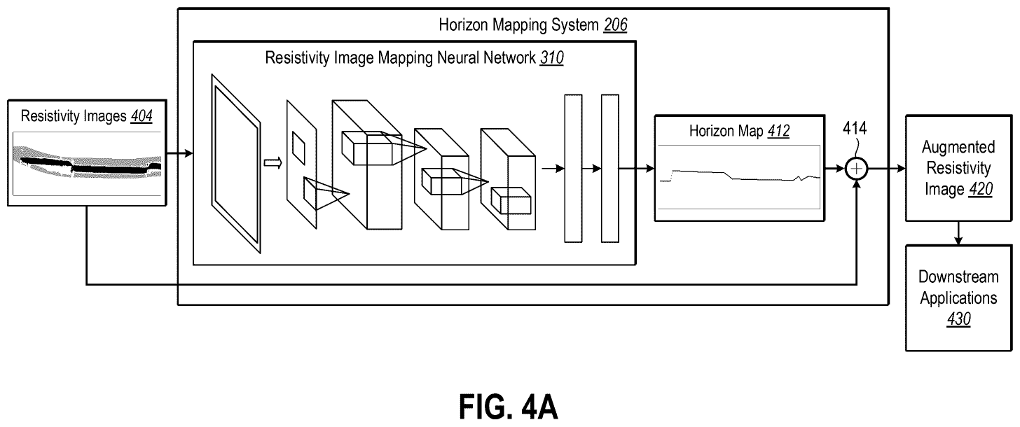

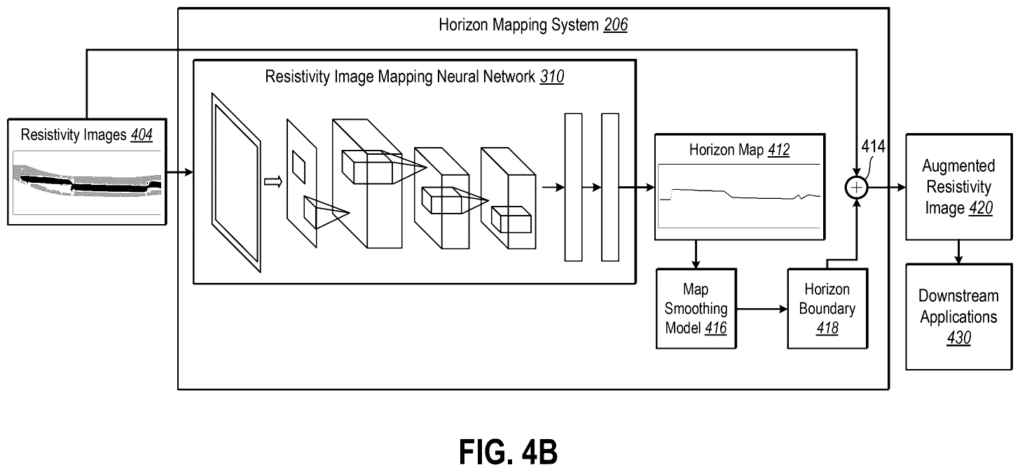

Once trained, in various implementations, the horizon mapping system 206 uses the resistivity image mapping neural network 310 to automatically generate horizon maps of geosphere resistivity sections with resistivity images and generate augmented (e.g., labeled) resistivity images (e.g., inversion images). FIGS. 4A-4B illustrate block diagram examples of using a horizon mapping system to generate horizon maps and augmented resistivity images according to some implementations.

As shown, in FIGS. 4A-4B, the resistivity image manager 210 includes the resistivity image mapping neural network 310. In these figures, the resistivity image mapping neural network 310 represents a trained model with tuned neural network layers and other trained components. The resistivity image mapping neural network 310 generates a horizon map 412 from a resistivity image 404. Additionally, FIGS. 4A-4B include downstream applications 430, which will be discussed below.

In various implementations, the resistivity image 404 includes real-time data. For example, as the horizon mapping system 206 receives resistivity images and/or inversion images from a subsurface structure system and/or a subsurface structure system, the horizon mapping system 206 generates one or more horizon maps. The horizon mapping system 206 may then efficiently and accurately generate augmented resistivity images in real time using the resistivity image mapping neural network 310 and other components.

In some implementations, the resistivity image 404 corresponds to different types of data. In one example, the resistivity image 404 includes penetration depth data of EM waves in a formation (e.g., AP50). In another example, the resistivity image 404 includes resistivity data obtained from a current pulse data measured through an electrode that measures the voltage response at another electrode (e.g., Pulsed Active Electrode PAE data).

Turning specifically to FIG. 4A, as shown, the horizon mapping system 206 includes an image augmenter 414. The image augmenter 414 generates an augmented resistivity image 420 from the resistivity image 404 and the horizon map 412. For example, the image augmenter 414 may merge, fuse, vote, and/or blend the pixels of the horizon within the horizon map 412 with the resistivity image 404 to generate the augmented resistivity image 420. Accordingly, in various implementations, the augmented resistivity image 420 includes labels indicating one or more horizons of a reservoir (or another trained geological feature).

Furthermore, depending on the model type of the resistivity image mapping neural network 310, the augmented resistivity image 420 may include labels for different horizon types (e.g., a top reservoir boundary, a bottom reservoir boundary, a water contact interlayer boundary, or an oil contact interlayer boundary). Additionally, in various implementations, the horizon map 412 includes levels of uncertainty determined by the resistivity image mapping neural network 310 (e.g., with percentage labels or grayscale-masked pixels).

In one or more implementations, the horizon mapping system 206 includes multiple resistivity image mapping neural networks trained to detect different horizon types. In some instances, the horizon mapping system 206 may combine the different horizon maps generated by the different resistivity image mapping neural networks. For example, a top reservoir resistivity image mapping neural network generates a top horizon map and a bottom reservoir resistivity image mapping neural network generates a bottom horizon map. The horizon mapping system 206 uses the image augmenter to generate a combined horizon map with both horizons and/or add both horizons to the resistivity image 404 to generate the augmented resistivity image 420 with both horizons.

As noted above, FIG. 4A includes the downstream applications 430. In various implementations, the horizon mapping system 206 uses the augmented resistivity image 420 for downstream applications 430. One example is automated geosteering. For instance, the augmented resistivity image 420 is used to adjust a drill bit's trajectory to avoid contact with a reservoir boundary. Another example is using the augmented resistivity image 420 to define zones of interest such as a distribution of lithology.

As a further example, the augmented resistivity image 420 is used in downstream models and workflows. For example, the horizon mapping system 206 uses the augmented resistivity image 420 to improve the accuracy of other models that map subsurface geological features. For instance, the horizon mapping system 206 provides the augmented resistivity image 420 as an input to a system that performs petrophysics modeling. In another instance, the horizon mapping system 206 uses the augmented resistivity image 420 to improve information about the lithology subsurface distribution (e.g., sands, shales, shaly sands, etc.) and/or reservoir properties (e.g., porosity, saturation, etc.) expected in a section of the geosphere being drilled.

In some implementations, the augmented resistivity image 420 is reviewed by a user. For example, a WPE reviews the reservoir boundary labels and makes necessary boundary adjustments. The horizon mapping system 206 may then incorporate these inputs to further train the resistivity image mapping neural networks of the resistivity image mapping neural network 310. In some implementations, a WPE uses the augmented image results to determine corrections to a trajectory path or to make other decisions.

FIG. 4B expands upon the concepts included in FIG. 4A. As shown, the horizon mapping system in FIG. 4B also includes a map smoothing model 416 and a horizon boundary 418.

In various implementations, the horizon mapping system 206 uses the map smoothing model 416 to determine a horizon boundary 418 (e.g., horizon line) by smoothing and/or extracting the horizon from the horizon map 412. In some instances, the map smoothing model 416 uses one or more smoothing algorithms to determine the horizon boundary 418. For example, the map smoothing model 416 uses confidence probability values in the horizon map 412 to determine the expected value (e.g., mean) of the position of the horizon to determine the horizon boundary 418. Then, as described above, in various implementations, the horizon mapping system 206 uses the image augmenter 414 to generate the augmented resistivity image 420 from the resistivity image 404 and the horizon boundary 418.

FIG. 5A-5B illustrate block diagram examples of generating the synthetic training data from a resistivity generation model according to some implementations. In particular, FIG. 5A shows a block diagram example of generating synthetic training data and FIG. 5B shows examples of synthetic resistivity images.

FIG. 5A includes synthetic horizontal well data 502 and resistivity data from vertical wells 504. In various implementations, the horizon mapping system 206 and/or another system generate the synthetic horizontal well data 502 using various subsurface models based on subsurface geological feature measurements. For example, the horizon mapping system 206 uses geological measurements, well logs, seismic data, and interpreted faults to randomly populate data for the synthetic horizontal well data 502, which shows the locations of surfaces, faults, and geosphere resistivity. The horizon mapping system 206 may also generate or obtain the synthetic horizontal well data 502 using other methods.

In one or more implementations, the horizon mapping system 206 and/or another system utilize the resistivity data from vertical wells 504 using various subsurface models based on one or more resistivity data generation models. For instance, the horizon mapping system 206 populates the resistivity data from vertical wells 504 based on vertical electrical sounding data acquired from well measurements (e.g., populating the synthetic wells with values obtained from nearby locations). Additionally, the horizon mapping system 206 may also generate or obtain the resistivity data from vertical wells 504 using other methods.

As shown, FIG. 5A includes a resistivity generation model 506. In one or more implementations, the resistivity generation model 506 simulates a geosphere resistivity response based on subsurface geological feature data. For example, the horizon mapping system 206 uses the resistivity generation model 506 to generate simulated or synthetic resistivity data based on the synthetic horizontal well data 502 and the resistivity data from vertical wells 504. In some cases, the horizon mapping system 206 determines resistivity measurements for subsurface geological features from the synthetic horizontal well data 502, which includes the resistivity data from vertical wells 504.

The horizon mapping system 206 uses the resistivity generation model 506 to generate a synthetic resistivity image 508. For example, the resistivity generation model 506 generates a resistivity inversion image from the simulated data. In various implementations, the resistivity inversion image represents a longitudinal electromagnetic (EM) resistivity image.

Additionally, the synthetic resistivity image 508 corresponds to a horizon ground truth map 510 generated from the synthetic resistivity image 508. For instance, because the synthetic resistivity image 508 is generated synthetically, it includes a well-defined, highly accurate horizon boundary, which the horizon mapping system uses to generate the horizon ground truth map 510. This high accuracy allows a resistivity image mapping neural network to be efficiently and accurately trained and implemented.

Based on the type of models and approaches used, the horizon mapping system 206 may generate training data of different dimensions. For example, the horizon mapping system 206 may generate resistivity images that are 1D, 2D, or 3D along with corresponding horizon ground truth maps. As shown, the images in FIG. 5A represent 2D images.

Additionally, in various implementations, the horizon mapping system 206 generates a training dataset that includes image pairs with synthetic resistivity images and corresponding horizon ground truth maps. For example, the horizon mapping system 206 sub-crops portions of the pair to generate additional training images with which to train a resistivity image mapping neural network. The horizon mapping system 206 may sub-crop random vertical widths to generate the training dataset.

In various implementations, the horizon mapping system 206 generates a robust training dataset by adding noise and other modifications to the synthetic resistivity images. For instance, the horizon mapping system 206 uses a noise generation model 514 to create a robust synthetic resistivity image 516. The noise generation model 514 may apply modifications to the synthetic resistivity image 508, including horizontal image flipping, vertical image flipping, random image rotation up to 90 degrees, random brightness modification, random contrast modification, color jitter modification, and/or Gaussian noise modification.

In many instances, for a robust synthetic resistivity image 516 generated from a synthetic resistivity image 508 paired a horizon ground truth map 510, the horizon mapping system 206 pairs the robust synthetic resistivity image 516 with the horizon ground truth map 510. This way, a robust synthetic resistivity image, with its additional noise and alterations, aligns with a highly accurate horizon ground truth map, further improving efficiency and accuracy for a trained resistivity image mapping neural network.

As mentioned above, FIG. 5B provides examples of synthetic resistivity images 518 generated by the resistivity generation model 506 in FIG. 5A. The horizon mapping system 206 may generate horizon ground truth maps for these synthetic resistivity images. In addition, the horizon mapping system 206 may create or generate robust synthetic resistivity images of these synthetic resistivity images, as described earlier. The horizon mapping system 206 may generate a large set of synthetic resistivity image pairs, robust synthetic resistivity image pairs, and/or sub-sets of these image pairs to create training data for a resistivity image mapping neural network.

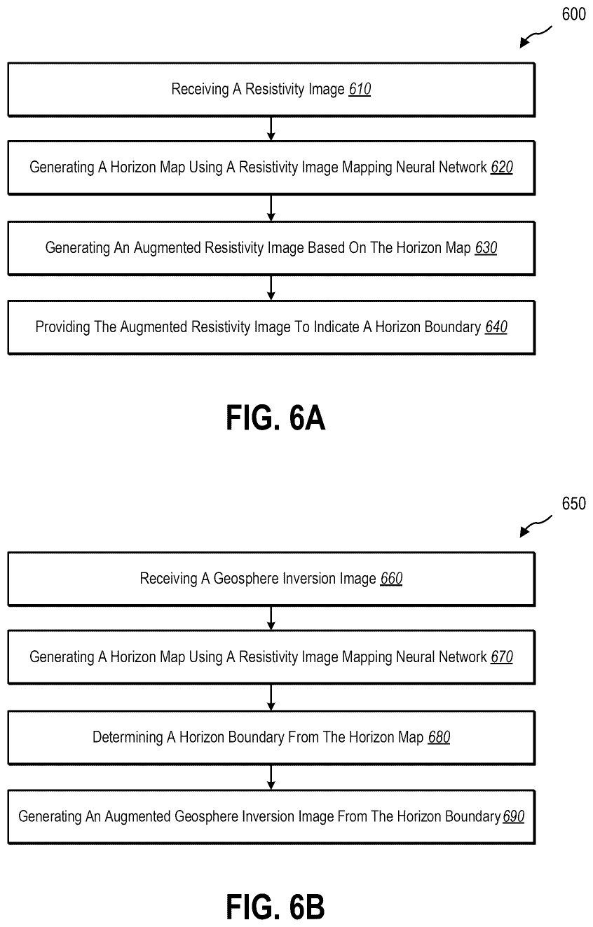

Now turning to FIGS. 6A-6B, each of these figures illustrates an example flowchart that includes a series of acts for using the horizon mapping system according to some implementations. In particular, both FIGS. 6A-6B illustrate an example series of acts representing a computer-implemented method for automatically determining a subsurface horizon in a drilling system using a resistivity image mapping neural network.

While FIGS. 6A-6B each illustrates a series of acts according to one or more implementations, alternative implementations may omit, add to, reorder, and/or modify any of the acts shown. Furthermore, the acts of FIGS. 6A-6B may be performed as part of a method (e.g., a computer-implemented method). Alternatively, a computer-readable medium may include instructions that, when executed by a processing system with a processor, cause a computing device to perform the acts of FIGS. 6A-6B.

In some implementations, a system (e.g., a processing system comprising a processor) may perform the acts of FIGS. 6A-6B. For example, the acts include a system that includes a processing system and computer memory including instructions that, when executed by the processing system, cause the system to perform various actions or steps.

Turning now to FIG. 6A, this figure includes a series of acts 600, with act 610 of receiving a resistivity image. For instance, in example implementations, the act 610 involves receiving a resistivity image of a geosphere resistivity section of a subsurface feature.

As further shown, the series of acts 600 includes act 620 of generating a horizon map using a resistivity image mapping neural network. For instance, in example implementations, the act 620 involves generating a horizon map that shows or displays a resistivity change interface using a resistivity image mapping neural network from the resistivity image.

As further shown, the series of acts 600 includes act 630 of generating an augmented resistivity image based on the horizon map. For instance, in example implementations, the act 630 involves generating an augmented resistivity image based on the horizon map and the resistivity image.

Furthermore, the series of acts 600 includes act 640 of providing the augmented resistivity image to indicate a horizon boundary. For instance, in example implementations, the act 640 involves providing the augmented resistivity image for display on a computing device to indicate a horizon boundary within the geosphere resistivity section of the subsurface feature.

In some instances, the series of acts 600 includes additional acts. For example, in some cases, the series of acts 600 includes creating or generating the resistivity image mapping neural network to determine resistivity change interfaces based on synthetic geosphere modeled data.

In some cases, the synthetic geosphere modeled data is generated by synthetic geosphere resistivity data. In some cases, the series of acts 600 includes automatically generating the augmented resistivity image based on real time resistivity measurements. In some cases, the horizon map includes a top or base reservoir boundary. In some cases, the series of acts 600 includes determining a horizon boundary from the horizon map using a map smoothing model; and generating the augmented resistivity image by combining the horizon boundary with the resistivity image. In some cases, the horizon map includes indications of horizon uncertainty. In some cases, the horizon map includes both a top reservoir boundary and a base reservoir boundary. In some cases, the horizon map includes a water boundary of the subsurface feature.

In some cases, the series of acts 600 includes performing resistivity measurements using a resistivity sensor to obtain a resistivity distribution; generating a geosphere inversion image from the resistivity distribution; and providing the geosphere inversion image to the resistivity image mapping neural network as the resistivity image. In some cases, the series of acts 600 includes generating the geosphere inversion image as a downhole operation in a bottomhole assembly based on real-time resistivity measurements; and generating the horizon map in the bottomhole assembly. In some cases, the resistivity image mapping neural network is a Monte Carlo dropout prediction model. In some cases, the resistivity image and the augmented resistivity image are one-dimensional (1D) images. In some cases, the resistivity image and the augmented resistivity image are three-dimensional (3D) images.

In some cases, the horizon map includes a top or base reservoir boundary. In some cases, the series of acts 600 includes automatically generating the augmented resistivity image based on real time resistivity measurements. In some cases, the resistivity image and the augmented resistivity image are two-dimensional (2D) images.

Turning now to FIG. 6B, this figure includes series of acts 650 having the act 660 of receiving a geosphere inversion image. For instance, in example implementations, the act 660 involves receiving a geosphere inversion image of a geosphere resistivity section of a subsurface feature.

As further shown, the series of acts 650 includes act 670 of generating a horizon map using a resistivity image mapping neural network. For instance, in example implementations, the act 670 involves generating a horizon map that displays or shows a resistivity change interface using a resistivity image mapping neural network from the geosphere inversion image.

As further shown, the series of acts 650 includes act 680 of determining a horizon boundary from the horizon map. For instance, in example implementations, the act 680 involves determining a horizon boundary from the horizon map using a map smoothing model.

As further shown, the series of acts 650 includes act 690 of generating an augmented geosphere inversion image from the horizon boundary. For instance, in example implementations, the act 690 involves creating or generating an augmented geosphere inversion image by combining the horizon boundary with the geosphere inversion image.

In some cases, the series of acts 650 includes providing the augmented geosphere inversion image for display on a computing device to indicate the horizon boundary within the geosphere resistivity section of the subsurface feature.

FIG. 7 illustrates certain components that may be included within a computer system 700. The computer system 700 may be used to implement the various computing devices, components, and systems described herein (e.g., by performing computer-implemented instructions). As used herein, a “computing device” refers to electronic components that perform a set of operations based on a set of programmed instructions. Computing devices include groups of electronic components, client devices, server devices, etc.

In various implementations, the computer system 700 represents one or more of the client devices, server devices, or other computing devices described above. For example, the computer system 700 may refer to various types of network devices capable of accessing data on a network, a cloud computing system, or another system. For instance, a client device may refer to a mobile device such as a mobile telephone, a smartphone, a personal digital assistant (PDA), a tablet, a laptop, or a wearable computing device (e.g., a headset or smartwatch). A client device may also refer to a non-mobile device such as a desktop computer, a server node (e.g., from another cloud computing system), or another non-portable device.

The computer system 700 includes a processing system including a processor 701. The processor 701 may be a general-purpose single- or multi-chip microprocessor (e.g., an Advanced Reduced Instruction Set Computer (RISC) Machine (ARM)), a special-purpose microprocessor (e.g., a digital signal processor (DSP)), a microcontroller, a programmable gate array, etc. The processor 701 may be referred to as a central processing unit (CPU) and may cause computer-implemented instructions to be performed. Although the processor 701 shown is just a single processor in the computer system 700 of FIG. 7, in an alternative configuration, a combination of processors (e.g., an ARM and DSP) could be used.

The computer system 700 also includes memory 703 in electronic communication with the processor 701. The memory 703 may be any electronic component capable of storing electronic information. For example, the memory 703 may be embodied as random-access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM), registers, and so forth, including combinations thereof.

The instructions 705 and the data 707 may be stored in the memory 703. The instructions 705 may be executable by the processor 701 to implement some or all of the functionality disclosed herein. Executing the instructions 705 may involve the use of the data 707 that is stored in the memory 703. Any of the various examples of modules and components described herein may be implemented, partially or wholly, as instructions 705 stored in memory 703 and executed by the processor 701. Any of the various examples of data described herein may be among the data 707 that is stored in memory 703 and used during the execution of the instructions 705 by the processor 701.

A computer system 700 may also include one or more communication interface(s) 709 for communicating with other electronic devices. The one or more communication interface(s) 709 may be based on wired communication technology, wireless communication technology, or both. Some examples of the one or more communication interface(s) 709 include a Universal Serial Bus (USB), an Ethernet adapter, a wireless adapter that operates according to an Institute of Electrical and Electronics Engineers (IEEE) 702.11 wireless communication protocol, a Bluetooth® wireless communication adapter, and an infrared (IR) communication port.

A computer system 700 may also include one or more input device(s) 711 and one or more output device(s) 713. Some examples of the one or more input device(s) 711 include a keyboard, mouse, microphone, remote control device, button, joystick, trackball, touchpad, and light pen. Some examples of the one or more output device(s) 713 include a speaker and a printer. A specific type of output device that is typically included in a computer system 700 is a display device 715. The display device 715 used with implementations disclosed herein may use any suitable image projection technology, such as liquid crystal display (LCD), light-emitting diode (LED), gas plasma, electroluminescence, or the like. A display controller 717 may also be provided, for converting data 707 stored in the memory 703 into text, graphics, and/or moving images (as appropriate) shown on the display device 715.

The various components of the computer system 700 may be coupled together by one or more buses, which may include a power bus, a control signal bus, a status signal bus, a data bus, etc. For clarity, the various buses are illustrated in FIG. 7 as a bus system 719.

This disclosure describes a subjective data application system in the framework of a network. In this disclosure, a “network” refers to one or more data links that enable electronic data transport between computer systems, modules, and other electronic devices. A network may include public networks such as the Internet as well as private networks. When information is transferred or provided over a network or another communication connection (either hardwired, wireless, or both), the computer correctly views the connection as a transmission medium. Transmission media may include a network and/or data links that carry required program code in the form of computer-executable instructions or data structures, which may be accessed by a general-purpose or special-purpose computer.

In addition, the network described herein may represent a network or a combination of networks (such as the Internet, a corporate intranet, a virtual private network (VPN), a local area network (LAN), a wireless local area network (WLAN), a cellular network, a wide area network (WAN), a metropolitan area network (MAN), or a combination of two or more such networks) over which one or more computing devices may access the various systems described in this disclosure. Indeed, the networks described herein may include one or multiple networks that use one or more communication platforms or technologies for transmitting data. For example, a network may include the Internet or other data link that enables transporting electronic data between respective client devices and components (e.g., server devices and/or virtual machines thereon) of the cloud computing system.

Further, upon reaching various computer system components, program code means in the form of computer-executable instructions or data structures may be transferred automatically from transmission media to non-transitory computer-readable storage media (devices), or vice versa. For example, computer-executable instructions or data structures received over a network or data link may be buffered in random-access memory (RAM) within a network interface module (NIC), and then it is eventually transferred to computer system RAM and/or to less volatile computer storage media (devices) at a computer system. Thus, it should be understood that computer-readable storage media (devices) may be included in computer system components that also (or even primarily) use transmission media.

Computer-executable instructions include instructions and data that, when executed by a processor, cause a general-purpose computer, special-purpose computer, or special-purpose processing device to perform a certain function or group of functions. In some implementations, computer-executable and/or computer-implemented instructions are executed by a general-purpose computer to turn the general-purpose computer into a special-purpose computer implementing elements of the disclosure. The computer-executable instructions may include, for example, binaries, intermediate format instructions such as assembly language, or even source code. Although the subject matter has been described in language specific to structural features and/or methodological acts, it is to be understood that the subject matter defined in the appended claims is not necessarily limited to the features or acts described above. Rather, the described features and acts are disclosed as example forms of implementing the claims.

Those skilled in the art will appreciate that the disclosure may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, and the like. The disclosure may also be practiced in distributed system environments where local and remote computer systems, which are linked (either by hardwired data links, wireless data links, or a combination of hardwired and wireless data links) through a network, both perform tasks. In a distributed system environment, program modules may be located in both local and remote memory storage devices.

The techniques described herein may be implemented in hardware, software, firmware, or any combination thereof unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium, including instructions that, when executed by at least one processor, perform one or more of the methods described herein (including computer-implemented methods). The instructions may be organized into routines, programs, objects, components, data structures, etc., which may perform particular tasks and/or implement particular data types, and which may be combined or distributed as desired in various implementations.

Computer-readable media may be any available media that may be accessed by a general-purpose or special-purpose computer system. Computer-readable media that store computer-executable instructions are non-transitory computer-readable storage media (devices). Computer-readable media that carry computer-executable instructions are transmission media. Thus, by way of example, implementations of the disclosure may include at least two distinctly different kinds of computer-readable media: non-transitory computer-readable storage media (devices) and transmission media.

As used herein, computer-readable storage media (devices) may include RAM, ROM, EEPROM, CD-ROM, solid-state drives (SSDs) (e.g., based on RAM), Flash memory, phase-change memory (PCM), other types of memory, other optical disk storage, magnetic disk storage or other magnetic storage devices, or any other medium which may be used to store desired program code means in the form of computer-executable instructions or data structures and which may be accessed by a general-purpose or special-purpose computer.

The steps and/or actions of the methods described herein may be interchanged with one another without departing from the scope of the claims. In other words, unless a specific order of steps or actions is required for the proper operation of the method that is being described, the order and/or use of specific steps and/or actions may be modified without departing from the scope of the claims.

The term “determining” encompasses a wide variety of actions and, therefore, “determining” may include calculating, computing, processing, deriving, investigating, looking up (e.g., looking up in a table, a data repository, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The terms “comprising,” “including,” and “having” are intended to be inclusive and mean that there may be additional elements other than the listed elements. Additionally, it should be understood that references to “one implementation” or “implementations” of the present disclosure are not intended to be interpreted as excluding the existence of additional implementations that also incorporate the recited features. For example, any element or feature described concerning an implementation herein may be combinable with any element or feature of any other implementation described herein, where compatible.

The present disclosure may be embodied in other specific forms without departing from its spirit or characteristics. The described implementations are to be considered illustrative and not restrictive. The scope of the disclosure is indicated by the appended claims rather than by the foregoing description. Changes that come within the meaning and range of equivalency of the claims are to be embraced within their scope.

What is claimed is:

1. A computer-implemented method for determining a subsurface horizon in a drilling system comprising:
receiving a resistivity image of a geosphere resistivity section of a subsurface feature;
generating a horizon map that shows a resistivity change interface using a resistivity image mapping neural network from the resistivity image;
generating an augmented resistivity image based on the horizon map and the resistivity image; and
providing the augmented resistivity image for display on a computing device to indicate a horizon boundary within the geosphere resistivity section of the subsurface feature.

2. The computer-implemented method of claim 1, further comprising generating the resistivity image mapping neural network to determine resistivity change interfaces based on synthetic geosphere modeled data.

3. The computer-implemented method of claim 2, wherein the synthetic geosphere modeled data is generated by synthetic geosphere resistivity data.

4. The computer-implemented method of claim 1, further comprising automatically generating the augmented resistivity image based on real time resistivity measurements.

5. The computer-implemented method of claim 1, wherein the horizon map includes a top or base reservoir boundary.

6. The computer-implemented method of claim 1, further comprising:
determining the horizon boundary from the horizon map using a map smoothing model; and
generating the augmented resistivity image by combining the horizon boundary with the resistivity image.

7. The computer-implemented method of claim 1, wherein the horizon map includes indications of horizon uncertainty.

8. The computer-implemented method of claim 1, wherein the horizon map includes both a top reservoir boundary and a base reservoir boundary.

9. The computer-implemented method of claim 1, wherein the horizon map includes a water boundary of the subsurface feature.

10. The computer-implemented method of claim 1, further comprising:
performing resistivity measurements using a resistivity sensor to obtain a resistivity distribution;
generating a geosphere inversion image from the resistivity distribution; and
providing the geosphere inversion image to the resistivity image mapping neural network as the resistivity image.

11. The computer-implemented method of claim 10, further comprising:
generating the geosphere inversion image as a downhole operation in a bottomhole assembly based on real-time resistivity measurements; and
generating the horizon map in the bottomhole assembly.

12. The computer-implemented method of claim 1, wherein the resistivity image mapping neural network is a Monte Carlo dropout prediction model.

13. The computer-implemented method of claim 1, wherein the resistivity image and the augmented resistivity image are one-dimensional (1D) images.

14. The computer-implemented method of claim 1, wherein the resistivity image and the augmented resistivity image are three-dimensional (3D) images.

15. A system, comprising:
a resistivity image mapping neural network trained from synthetic geosphere modeled data to determine resistivity change interfaces; and
a processing system and memory, the memory including instructions which, when accessed by the processing system cause the processing system to perform operations of:
receiving a resistivity image of a geosphere resistivity section of a subsurface feature;
generating a horizon map that shows a resistivity change interface using the resistivity image mapping neural network from the resistivity image;
generating an augmented resistivity image based on the horizon map and the resistivity image; and
providing the augmented resistivity image for display on a computing device to indicate a horizon boundary within the geosphere resistivity section of the subsurface feature.

16. The system of claim 15, wherein the horizon map includes a top or base reservoir boundary.

17. The system of claim 15, the operations further comprise automatically generating the augmented resistivity image based on real time resistivity measurements.

18. The system of claim 15, wherein the resistivity image and the augmented resistivity image are two-dimensional (2D) images.

19. A computer-implemented method for determining a subsurface horizon in a drilling system comprising:
receiving a geosphere inversion image of a geosphere resistivity section of a subsurface feature;
generating a horizon map that shows a resistivity change interface using a resistivity image mapping neural network from the geosphere inversion image;
determining a horizon boundary from the horizon map using a map smoothing model; and
generating an augmented geosphere inversion image by combining the horizon boundary with the geosphere inversion image.

20. The computer-implemented method of claim 19, further comprising providing the augmented geosphere inversion image for display on a computing device to indicate the horizon boundary within the geosphere resistivity section of the subsurface feature.
